(19) United States
(12) Patent Application Publication
(10) Pub. No.: US 2024/0005067 A1
(43) Pub. Date: Jan. 4, 2024

(54) METHOD AND SYSTEM FOR MODAL PREDICTION AND ANALYSIS OF GEOTECHNICAL ENGINEERING STRUCTURE

(71) Applicant: SHENZHEN UNIVERSITY, Shenzhen (CN)

(72) Inventors: Xiaohua Bao, Shenzhen (CN); Jun Shen, Shenzhen (CN); Xiangsheng Chen, Shenzhen (CN); Hongzhi Cui, Shenzhen (CN)

(21) Appl. No.: 18/090,267

(22) Filed: Dec. 28, 2022

(30) Foreign Application Priority Data
Jun. 13, 2022 (CN) 202210659109.0

(51) Int. Cl. G06F 30/27; G06F 30/13; G06Q 10/0639; G06Q 50/08

(52) U.S. Cl. CPC G06F 30/27; G06F 30/13; G06Q 10/06393; G06Q 50/08

(57) ABSTRACT

Disclosed are a method and system for modal prediction and analysis of a geotechnical engineering structure, which relate to the technical field of structural health monitoring of civil engineering. It solves various influencing elements that affect implementation of construction scheme during construction. The influencing elements comprise construction environment, load conditions, drainage and future precipitation. Taking the future precipitation as an example, the construction of geotechnical engineering structure will be affected in rainy days, even force data will change. The method comprises: obtaining force information of geotechnical engineering structure actually obtained and structural deformation data under different force information as training data; revising the analysis algorithm of geotechnical engineering structure based on the training data and actual data by applying a built neural network algorithm.

### CROSS-REFERENCE TO RELATED APPLICATION

This application claims the priority and benefit of Chinese patent application serial no. 202210659109.0, filed on Jun. 13, 2022. The entirety of Chinese patent application serial no. 202210659109.0 is hereby incorporated by reference herein and made a part of this specification.

### TECHNICAL FIELD

This application relates to a technical field of structural health monitoring of civil engineering, and, in particular, to a method and system for modal prediction and analysis of a geotechnical engineering structure.

### BACKGROUND

In recent ten years, urban underground space has been developed and utilized on a grand scale. The number of underground construction projects in densely populated and built-up urban areas has risen sharply. The development and intensive utilization of urban underground space is a new space for urban development and an inevitable choice to solve the problem of insufficient urban resource carrying capacity.

Large urban complexes, super large building communities, and super large neighborhood projects are constantly emerging. At the same time, engineering accidents and environmental problems caused by geotechnical engineering development activities in underground space, particularly by foundation pit excavation are increasing. In view of the increasingly complex shape, deep excavation depth and large excavation area of urban geotechnical engineering, and the close distance between the construction site and the existing buildings (structures) of foundation pit engineering in prosperous urban areas, lack of accurate understanding of the geotechnical engineering construction under complex conditions will lead to a series of engineering risk problems. For example, with the large-scale development and utilization of underground space in cities, frequent deformation of the geotechnical engineering enclosure system is too large or even unstable, surface cracks even lead to collapse of urban roads and too large surface settlement, resulting in damage or even collapse of adjacent buildings and structures and urban lifelines. The consequences will be unimaginable.

In relevant technologies, prior to design and construct geotechnical engineering, relevant designers would conduct manual mechanical simulation calculation to make analysis and prediction to the structure based on the project drawings and data, so as to facilitate the determination of the subsequent structural construction scheme.

In the above relevant technologies, it is believed that there are the following defects: on the one hand, manual mechanical simulation calculation and analysis are troublesome and time-consuming; on the other hand, there is split between geotechnical engineering design and construction, namely, the construction scheme planning based on manual mechanical simulation analysis is ideal. However, there are various influencing elements that affect the implementation of the construction scheme during the construction in fact. The influencing elements include construction environment, load conditions, drainage and future precipitation. Taking future precipitation as an example, rainy days will affect the construction of geotechnical engineering structures, and even affect their force data such that it changes.

### SUMMARY

A method and system for modal prediction and analysis of a geotechnical engineering structure are disclosed, in order to more accurately analyze the predicted mechanical statuses of the geotechnical engineering structure, and to adjust the overall algorithm in combination with the feedback of actual statuses, so as to continuously improve the prediction accuracy of the mechanical statuses of the geotechnical engineering structure.

In one aspect of the present disclosure, a method for modal prediction and analysis of a geotechnical engineering structure is disclosed, including:
obtaining a design model of the geotechnical engineering structure and status information of influencing elements during a planned geotechnical engineering, the influencing elements including construction environment, load conditions, drainage and future precipitation;
analyzing and determining an analysis algorithm of geotechnical engineering structure corresponding to the status information of influencing elements obtained according to a corresponding relationship between the status information of influencing elements and analysis algorithm of geotechnical engineering structure, and modal predicting the design model of the geotechnical engineering structure by using a corresponding analysis algorithm of geotechnical engineering structure, so as to calculate force information of the geotechnical engineering structure and modal deformation data of soil-structure under different force information as training data;
obtaining force information of the geotechnical engineering structure actually obtained and structural deformation data under different force information as actual data;
revising the analysis algorithm of geotechnical engineering structure based on the training data and actual data by applying a pre-built neural network algorithm.

By the above technical solution, it is possible to effectively analyze and determine an analysis algorithm of geotechnical engineering structure adaptive for the status information of influencing elements during the planned geotechnical engineering, so as to calculate the force information of the geotechnical engineering structure and the modal deformation data of soil-structure under different force information. In addition, the analysis algorithm of geotechnical engineering structure can be continuously revised by applying the neural network algorithm according to comparison between the actual conditions and theoretical conditions before and after, so as to continuously improve the prediction accuracy of the mechanical statuses of the geotechnical engineering structure.
optionally, a step of analyzing and determining an analysis algorithm of geotechnical engineering structure corresponding to the status information of influencing elements obtained including:
querying, whether there is an analysis algorithm of geotechnical engineering structure corresponding to the status information of influencing elements obtained, according to the corresponding relationship between the status information of influencing elements and analysis algorithm of geotechnical engineering structure;
if yes, using the analysis algorithm of geotechnical engineering structure corresponding to the status information of influencing elements obtained as the analysis algorithm of geotechnical engineering structure determined;
otherwise, querying an analysis algorithm of geotechnical engineering structure corresponding to status information of other influencing elements, and analyzing and determining an analysis algorithm of geotechnical engineering structure corresponding to status information of influencing elements with the highest similarity to the status information of influencing elements obtained, as an analysis algorithm of geotechnical engineering structure for the actual application.

How to use the analysis algorithm of geotechnical engineering structure corresponding to the status information of influencing elements is disclosed specially, especially considering that when there is no corresponding analysis algorithm of geotechnical engineering structure, an analysis algorithm of geotechnical engineering structure corresponding to the status information of influencing elements with the highest similarity to the status information of influencing factors obtained will be applied.

Optionally, a step of analyzing and determining an analysis algorithm of geotechnical engineering structure corresponding to status information of influencing elements with the highest similarity to the status information of influencing elements obtained comprises:
analyzing similarity between the status information of influencing elements obtained and status information of influencing elements involved in existing analysis algorithm of geotechnical engineering structure;
analyzing and determining the analysis algorithm of geotechnical engineering structure corresponding to status information of influencing elements with the highest similarity to the status information of influencing elements obtained based on the similarity between the status information of influencing elements obtained and status information of influencing elements involved in existing analysis algorithm of geotechnical engineering structure and influence ratio of preset influencing elements on the analysis algorithm of geotechnical engineering structure;
using the analysis algorithm of geotechnical engineering structure determined as the analysis algorithm of geotechnical engineering structure in the actual application.

The influence ratio of different influencing elements on the analysis algorithm of geotechnical engineering structure, and the similarity between the status information of influencing elements obtained and the status information of influencing elements involved in the existing analysis algorithm of geotechnical engineering structure are fully considered by the above technical solution, such that the status information of influencing elements with the highest similarity to the status information of influencing elements obtained can be effectively analyzed and determined, so as to more accurately and effectively analyze and determine the analysis algorithm of geotechnical engineering structure corresponding to the status information of influencing elements with the highest similarity to the status information of influencing elements obtained.

Optionally, a step of analyzing similarity between the status information of influencing elements obtained and status information of influencing elements involved in existing analysis algorithm of geotechnical engineering structure comprises:
analyzing time ratios of occurrence of different kinds of statuses of different influencing elements in the status information of influencing elements obtained;
analyzing and obtaining similarity of time ratios of occurrence between influencing elements involved in preset different analysis algorithms of geotechnical engineering structure and same one of the influencing elements, according to the time ratios of occurrence of different kinds of statuses of different influencing elements, time ratios of occurrence of corresponding kinds of statuses of the same one influencing element in the status information of influencing elements involved in the preset different analysis algorithms of geotechnical engineering structure;
analyzing and determining the similarity between the status information of influencing elements obtained and status information of influencing elements involved in existing analysis algorithm of geotechnical engineering structure, according to the similarity of time ratios of occurrence between influencing elements involved in preset different analysis algorithms of geotechnical engineering structure and the same one of the influencing elements, and the same influencing element, the time ratios of occurrence of different kinds of statuses of the same influencing element.

The time ratio of occurrence of different kinds of statuses of different influencing elements, and the time ratios of occurrence of the corresponding kinds of statuses of the same influencing element in the status information of influencing elements involved in the preset different analysis algorithms of geotechnical engineering structure are further considered in this technical solution, so that the similarity of the time ratios of occurrence between the influencing elements involved in different analysis algorithms of geotechnical engineering structure and the same influencing element obtained can be analyzed and obtained, which lays a foundation for subsequent analyzing of the similarity between the status information of influencing elements obtained and the status information of influencing elements involved in the existing analysis algorithm of geotechnical engineering structure.

Optionally, the method further comprises after a step of analyzing and determining an analysis algorithm of geotechnical engineering structure corresponding to status information of influencing elements with the highest similarity to the status information of influencing elements obtained but before a step of using the analysis algorithm of geotechnical engineering structure as an analysis algorithm of geotechnical engineering structure in the actual application:
obtaining similarity between status information corresponding to the analysis algorithm of geotechnical engineering structure determined and the status information of influencing elements obtained;
using the analysis algorithm of geotechnical engineering structure determined as the analysis algorithm of geotechnical engineering structure for the actual application, if the similarity of the status information exceeds a first preset similarity;
otherwise, analyzing information gap between the status information of influencing elements with the highest similarity to the status information of influencing elements obtained and the status information of influencing elements obtained;
predicting, analyzing and obtaining the analysis algorithm of geotechnical engineering structure in the actual application according to the information gap, the analysis algorithm of geotechnical engineering structure corresponding to status information of influencing elements with the highest similarity to the status information of influencing elements obtained, the corresponding relationship between status information of a single influencing element and analysis algorithm of geotechnical engineering structure by applying a preset prediction equation of an analysis algorithm of geotechnical engineering structure.

Possibility of low similarity of the status information can be further considered by the above technical solution. In this situation, the analysis algorithm of geotechnical engineering structure in the actual application is further predicted, analyzed and obtained according to the information gap between the status information corresponding to the corresponding algorithm and the status information of influencing elements obtained, in combination with the analysis algorithm of geotechnical engineering structure corresponding to the status information of influencing elements with the highest similarity, the corresponding relationship between status information of a single influencing element and the analysis algorithm of geotechnical engineering structure.

Optionally, a step of predicting and analyzing the analysis algorithm of geotechnical engineering structure in the actual application comprising:
obtaining the analysis algorithm of geotechnical engineering structure corresponding to status information of influencing elements with the highest similarity to the status information of influencing elements obtained, and the corresponding relationship between status information of a single influencing element and analysis algorithm of geotechnical engineering structure;
analyzing a ratio of single information gap between each influencing element contained in the status information of influencing elements with the highest similarity and the same influencing element contained in the status information of influencing elements obtained according to the information gap;
analyzing and obtaining effective influencing factors of each influencing element according to the ratio of single information gap of each influencing element, and the influence ratio of the preset influencing elements on the analysis algorithm of geotechnical engineering structure;
predicting, analyzing and obtaining the analysis algorithm of geotechnical engineering structure in the actual application by applying the following prediction equation of the preset analysis algorithm of geotechnical engineering structure:

Z=a*q1+q2*[b*(t1/tₜₒₜₐₗ)+c*(t2/tₜₒₜₐₗ)+d*(t3/tₜₒₜₐₗ)+e*(t4/tₜₒₜₐₗ)]
q1+q2=1, ttotal=t1+t2+t3+t4, where
Z is the analysis algorithm of geotechnical engineering structure in the actual application predicted,
a is the analysis algorithm of geotechnical engineering structure corresponding to status information of influencing elements with the highest similarity to the status information of influencing elements obtained,
q1 is weight coefficient of the analysis algorithm of geotechnical engineering structure corresponding to status information of influencing elements with the highest similarity to the status information of influencing elements obtained,
q2 is weight coefficient of the analysis algorithm corresponding to a single influencing element,
b is an analysis algorithm of geotechnical engineering structure corresponding to the first single influencing element,
t1 is an effective influencing factor of the first single influencing element,
c is an analysis algorithm of geotechnical engineering structure corresponding to the second single influencing element,
t2 is an effective influencing factor of the second single influencing element,
d is an analysis algorithm of geotechnical engineering structure corresponding to the third single influencing element,
t3 is an effective influencing factor of the third single influencing element,
e is an analysis algorithm of geotechnical engineering structure corresponding to the fourth single influencing element,
t4 is an effective influencing factor of the fourth single influencing element.

The effective influencing factors of each influencing element can be further analyzed and obtained by the above technical solution, wherein the analysis algorithm of geotechnical engineering structure in the actual application is predicted according to the effective influencing factors of each influencing element and the prediction equation of the analysis algorithm of geotechnical engineering structure.

Optionally, the method further comprises after a step of o obtaining force information of the geotechnical engineering structure actually obtained and structural deformation data under different force information as actual data but before a step of revising the analysis algorithm of geotechnical engineering structure:
analyzing and obtaining difference between the force information of the geotechnical engineering structure actually obtained as well as the structural deformation data under different force information and the calculated force information of the geotechnical engineering structure as well as structural deformation data under different force information;
if the difference exceeds a first preset value, stopping the subsequent steps, and sorting problems from high to low based on distribution probability and sending them to a terminal held by a person in charge of geotechnical engineering, according to distribution probability of problems with historical difference exceeding the first preset value with different exceeding degrees,
if the difference exceeds a second preset value but is lower than the first preset value, stopping the subsequent steps, and sorting problems from high to low based on distribution probability and sending them to the terminal held by the person in charge of geotechnical engineering, according to distribution probability of problems with historical difference exceeding the second preset value with different exceeding degrees;
otherwise, continuing the subsequent steps.

Different problems under different differences can be further considered with the above technical solution, so sorting according to problems probability can be made while sending to the person in charge, so that the person in charge can better solve the problems.

Optionally, the person in charge of geotechnical engineering is selected as follows:
analyzing working years of the person in charge of geotechnical engineering;
if the working years of the person in charge of geotechnical engineering are lower than preset working years, sending it with the notification information due to the difference exceeding the first preset value together to remaining technicians in charge of deep foundation pit project, and establishing a problem discussion group after the remaining technicians have confirmed to accept the relevant notification information;
otherwise, no special treatment.

A problem that the person in charge cannot effectively deal with problems due to his/her insufficient working years can be further considered by the above technical solution. In this case, the problem discussion group will be established to better solve problems.

Optionally, the method further comprises between a step of sorting problems from high to low based on distribution probability and a step of sending to the terminal held by the person in charge of geotechnical engineering:
analyzing problems whose distribution probability exceeds the preset probability;
selecting problems that rank before a preset position and marking them with a warning color the person in charge of geotechnical engineering prefers to from the problems whose distribution probability exceeds the preset probability.

The person in charge did not reply in time after receiving information, which is further considered by the above technical solution. In this case, the reminder method will be adjusted in time to make a second reminder.

In the second aspect, a system for modal prediction and analysis of a geotechnical engineering structure is disclosed, comprising:
a memory;
a processor; and
a program, which is stored on the memory and can run on the processor,
wherein the program can be loaded and executed on the processor, to realize the method for modal prediction and analysis of a geotechnical engineering structure as the first aspect of the present disclosure.

By the above technical scheme, it is possible to effectively analyze and determine an analysis algorithm of geotechnical engineering structure adaptive for the status information of influencing elements during the planned geotechnical engineering, so as to calculate the force information of the geotechnical engineering structure and the modal deformation data of soil-structure under different force information. In addition, the analysis algorithm of geotechnical engineering structure can be continuously revised by applying the neural network algorithm according to comparison between the actual conditions and theoretical conditions before and after.

To sum up, the mechanical conditions of the geotechnical engineering structure can be effectively predicted and analyzed by applying the existing analysis algorithm of geotechnical engineering structure; in addition, the theoretical value and actual value of the geotechnical engineering structure are fully considered, in combination with adjustment by neural network algorithm, to make the analysis algorithm of geotechnical engineering structure more accurate.

### BRIEF DESCRIPTION OF THE DRAWINGS

FIG. 1 is a flow diagram of the method for modal prediction and analysis of a geotechnical engineering structure in one embodiment of the present disclosure.

FIG. 2 is a flow diagram of a step of analyzing and determining an analysis algorithm of geotechnical engineering structure corresponding to the status information of influencing elements obtained in the other embodiment of the present disclosure.

FIG. 3 is a flow diagram of a step of analyzing and determining an analysis algorithm of geotechnical engineering structure corresponding to status information of influencing elements with the highest similarity to the status information of influencing elements obtained in the other embodiment of the present disclosure.

FIG. 4 is a flow diagram of a step of analyzing similarity between the status information of influencing elements obtained and status information of influencing elements involved in existing analysis algorithm of geotechnical engineering structure in the other embodiment of the present disclosure.

FIG. 5 is a flow diagram of a step after a step of analyzing and determining an analysis algorithm of geotechnical engineering structure corresponding to status information of influencing elements with the highest similarity to the status information of influencing elements obtained but before using it as an analysis algorithm of geotechnical engineering structure in the actual application in the other embodiment of the present disclosure.

FIG. 6 is a flow diagram of the method for modal prediction and analysis of a geotechnical engineering structure in the other embodiment of the present disclosure.

FIG. 7 is a flow diagram of a step after a step of obtaining actual force information of geotechnical engineering structure and structural deformation data under different force information as actual data but before a step of revising the analysis algorithm of geotechnical engineering structure in the other embodiment of the present disclosure.

FIG. 8 is a flow diagram of a step of selecting the person in charge of geotechnical engineering in the other embodiment of the present disclosure.

FIG. 9 is a flow diagram of a step between sorting problems from high to low based on distribution probability and sending them to the terminal held by the person in charge of geotechnical engineering in the other embodiment of the present disclosure.

### DESCRIPTION OF THE EMBODIMENTS

The present disclosure will be further described in detail below in combination with the drawings.

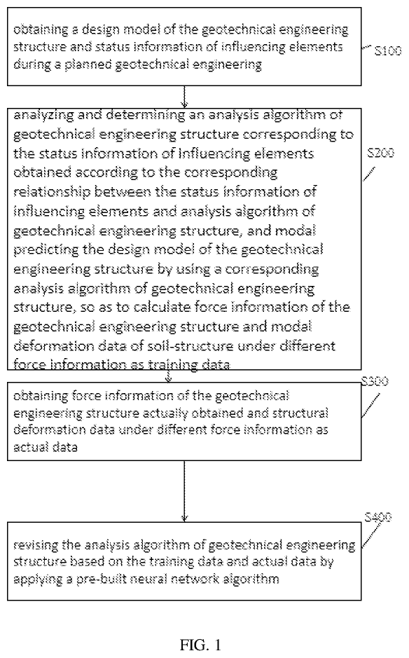

FIG. 1 shows a method for modal prediction and analysis of a geotechnical engineering structure, comprising:

step S100, obtaining a design model of the geotechnical engineering structure and status information of influencing elements during a planned geotechnical engineering.

The design model of the geotechnical engineering structure is established by BIM or relevant construction model system. The influencing elements include construction environment, load conditions, drainage and future precipitation. The status information of influencing elements during a planned geotechnical engineering can be obtained from a preset database storing the status information of influencing elements during the geotechnical engineering.

The construction environment can be obtained from a preset database storing the construction location of the design model of the geotechnical engineering structure; the load conditions can be obtained from a preset database storing the load conditions corresponding to the design model of the geotechnical engineering structure; drainage can be obtained from a preset database storing drainage conditions of the construction location of the design model of the geotechnical engineering structure; the future precipitation can be obtained by searching precipitation conditions of relevant future weather from network through crawler technology.

Step S200, analyzing and determining an analysis algorithm of geotechnical engineering structure corresponding to the status information of influencing elements obtained according to the corresponding relationship between the status information of influencing elements and analysis algorithm of geotechnical engineering structure, and modal predicting the design model of the geotechnical engineering structure by using a corresponding analysis algorithm of geotechnical engineering structure, so as to calculate force information of the geotechnical engineering structure and modal deformation data of soil-structure under different force information as training data.

The analysis algorithm of geotechnical engineering structure corresponding to the status information of influencing elements can be obtained from a preset database storing analysis algorithms of geotechnical engineering structure. Specifically, the analysis algorithm of geotechnical engineering structure is so formed: obtaining experimental data through a plurality of experiments under limiting conditions of relevant factors, and establishing empirical equation through more experimental data to form the analysis algorithm of geotechnical engineering structure.

The force information of the geotechnical engineering structure and the modal deformation data of soil-structure under different force information can be obtained as follows: establishing a simulation system of corresponding design model of the geotechnical engineering according to the analysis algorithm of geotechnical engineering structure; then analyzing and calculating the force information and the modal deformation data of soil-structure under different force information according to the input parameters of influencing elements and parameter information of some models through the simulation system.

Step S300, obtaining force information of the geotechnical engineering structure actually obtained and structural deformation data under different force information as actual data.

The force information of the geotechnical engineering structure actually obtained and the structural deformation data under different force information can be detected through a detection device actually configured to detect the force information of the geotechnical engineering structure and structural deformation data under different force information on the site. For example, a geotechnical engineering structure may contain columns, whose settlement data can be measured through a hydrostatic level, wherein stress of the columns can be obtained from the corresponding stress data which is detected by the reinforcement bar stress meter uniformly arranged around the columns.

Step S400, revising the analysis algorithm of geotechnical engineering structure based on the training data and actual data by applying a pre-built neural network algorithm.

The neural network algorithm is an algorithm mathematical model that simulates the behavior characteristics of animal neural networks and conducts distributed parallel information processing. The neural network algorithm mentioned in step S400 can use feedforward neural network, which is the most common type of neural networks in practice. The first layer is input, and the last layer is output.

In this disclosure, the training data is input and the actual data is output. The existing analysis algorithm of geotechnical engineering structure can be revised by multiple input and output data and inserting correlation coefficients into the original algorithms to make adjustment.

The implementation principle of the present embodiment is as follows:

An analysis algorithm of geotechnical engineering structure under corresponding influencing elements can be found according to the status information of influencing elements during the geotechnical engineering and the training data can be obtained according to the analysis algorithm of geotechnical engineering structure. The analysis algorithm of geotechnical engineering structure can be revised according to the actual data, the training data and the neural network algorithm, so as to further revise the analysis algorithm of geotechnical engineering structure under corresponding influencing conditions, such that a more precise analysis algorithm of geotechnical engineering structure can be used when facing corresponding conditions subsequently.

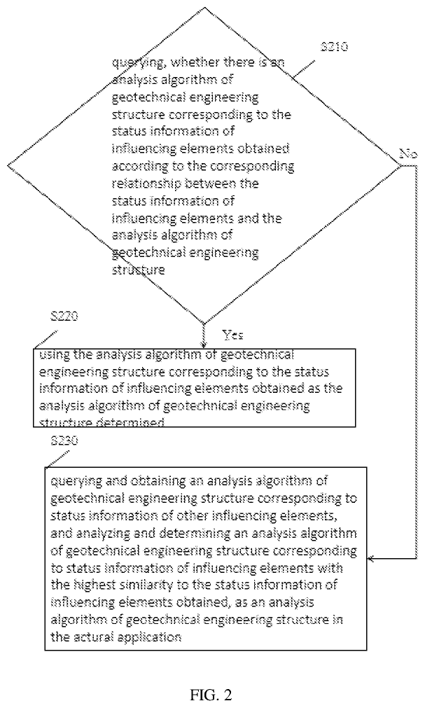

In step S200 of FIG. 1, the case that the analysis algorithm of geotechnical engineering structure corresponding to the status information of influencing elements obtained cannot be obtained from the corresponding relationship between the status information of influencing elements and the analysis algorithm of geotechnical engineering structure is further considered. In this case, the analysis algorithm of geotechnical engineering structure corresponding to the status information of influencing element should be further analyzed. For details refer to the embodiment shown in FIG. 2.

Referring to FIG. 2, a step of analyzing and determining an analysis algorithm of geotechnical engineering structure corresponding to the status information of influencing elements obtained mentioned in step S200 includes:

step S210, querying, whether there is an analysis algorithm of geotechnical engineering structure corresponding to the status information of influencing elements obtained according to the corresponding relationship between the status information of influencing elements and the analysis algorithm of geotechnical engineering structure. If yes, conducting step S220; otherwise conducting step S230.

Step S220, using the analysis algorithm of geotechnical engineering structure corresponding to the status information of influencing elements obtained as the analysis algorithm of geotechnical engineering structure determined.

Step S230, querying and obtaining an analysis algorithm of geotechnical engineering structure corresponding to status information of other influencing elements, and analyzing and determining an analysis algorithm of geotechnical engineering structure corresponding to status information of influencing elements with the highest similarity to the status information of influencing elements obtained, as an analysis algorithm of geotechnical engineering structure in the actual application.

The implementation principle of this embodiment is as follows:

When the case that the analysis algorithm of geotechnical engineering structure cannot be determined according to the corresponding relationship between the status information of influencing elements and the analysis algorithm of geotechnical engineering structure is effectively considered, an analysis algorithm of geotechnical engineering structure corresponding to the status information of influencing elements with the highest similarity to the status information of influencing elements obtained can be found as the analysis algorithm of geotechnical engineering structure in the actual application.

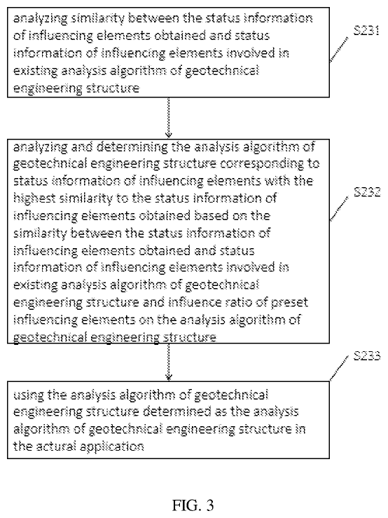

In step S230 of FIG. 2, when determining the similarity of the status information, it is necessary to consider the influence ratio of the influencing elements and the similarity of the status information to make a comprehensive judgment. Therefore, it is also necessary to further analyze and determine the analysis algorithm of geotechnical engineering structure corresponding to the status information of influencing elements with the highest similarity to the status information of influencing elements obtained. For details refer to the embodiment shown in FIG. 3.

Referring to FIG. 3, a step of analyzing and determining an analysis algorithm of geotechnical engineering structure corresponding to status information of influencing elements with the highest similarity to the status information of influencing elements obtained comprises:

Step S231, analyzing similarity between the status information of influencing elements obtained and status information of influencing elements involved in existing analysis algorithm of geotechnical engineering structure.

Step S232, analyzing and determining the analysis algorithm of geotechnical engineering structure corresponding to status information of influencing elements with the highest similarity to the status information of influencing elements obtained based on the similarity between the status information of influencing elements obtained and status information of influencing elements involved in existing analysis algorithm of geotechnical engineering structure and influence ratio of preset influencing elements on the analysis algorithm of geotechnical engineering structure.

The influence ratio of preset influencing elements on the analysis algorithm of geotechnical engineering structure can be obtained from a preset database storing the influence ratio of influencing elements on the analysis algorithm of geotechnical engineering structure. The specific calculation method of the influence ratio can be as follows: calculating the ratio of the average change of corresponding influencing elements to value corresponding to the overall analysis algorithm of geotechnical engineering structure; calculating the ratio of each influencing element to the overall analysis algorithm of geotechnical engineering structure; and then calculating the specific value between the ratio of each influencing element to the overall analysis algorithm of geotechnical engineering structure and the ratio of all the influencing elements to the overall analysis algorithm of geotechnical engineering structure, as the influence ratio of each influencing element to the analysis algorithm of geotechnical engineering structure.

For example, among the four influencing elements in the present disclosure, there are three influencing elements at this time, one of which does not work, and three of which are respectively influencing element A, influencing element B, and influencing element C. Among them, the influence ratio of the influencing element A is 30%, the influence ratio of the influencing element B is 50%, and the influence ratio of the influencing element C is 20%.

In addition, there are two sets of analysis algorithms of geotechnical engineering structure. Among them, the similarity of the same influencing element between the first set of analysis algorithm of geotechnical engineering structure and the influencing element A is 80%, the similarity of the same influencing element between the first set of analysis algorithm of geotechnical engineering structure and the influencing element B is 90%, and the similarity of the same influencing element between the first set of analysis algorithm of geotechnical engineering structure and the influencing element C is 90%, Then the similarity of the first set of analysis algorithm of geotechnical engineering structure is as follows: Y=0.8*0.3+0.9*0.5+0.9*0.2=0.87.

The similarity of the same influencing element between the second set of analysis algorithm of geotechnical engineering structure and the influencing element A is 70%, the similarity of the same influencing element between the second set of analysis algorithm of geotechnical engineering structure and the influencing element B is 80%, and the similarity of the same influencing element between the second set of analysis algorithm of geotechnical engineering structure and the influencing element C is 60%, Then the similarity of the second set of analysis algorithm of geotechnical engineering structure is as follows: Y=0.7*0.3+0.8*0.5+0.6*0.2=0.77.

To sum up, the second set of analysis algorithm of geotechnical engineering structure is selected.

Step S233, using the analysis algorithm of geotechnical engineering structure determined as the analysis algorithm of geotechnical engineering structure in the actual application.

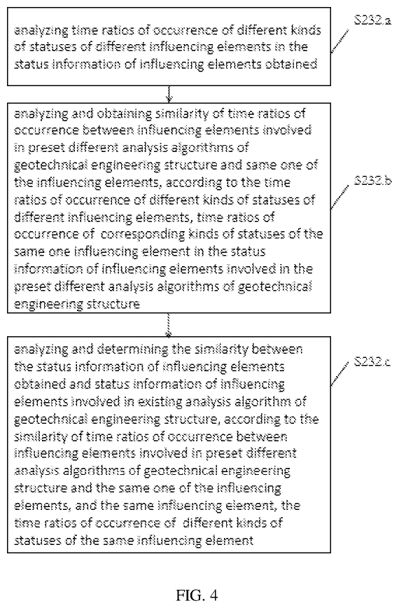

In step S232 of FIG. 3, in the process of analyzing similarity between the status information of influencing elements obtained and the status information of influencing elements involved in the existing analysis algorithm of geotechnical engineering structure, it is also necessary to consider the type and time ratio of the influencing elements to better determine the similarity of status information. Therefore, it is necessary to further analyze the similarity between the status information of influencing elements obtained and the status information of influencing elements involved in the existing analysis algorithm of geotechnical engineering structure. For details refer to the embodiment shown in FIG. 4.

Referring to FIG. 4, a step of analyzing similarity between the status information of influencing elements obtained and status information of influencing elements involved in existing analysis algorithm of geotechnical engineering structure comprises:

Step S232.a, analyzing time ratios of occurrence of different kinds of statuses of different influencing elements in the status information of influencing elements obtained.

The time ratios of occurrence of different kinds of statuses of different influencing elements in the status information of influencing elements obtained can be obtained from a preset database storing the time ratios of occurrence of different kinds of statuses of different influencing elements in the status information of influencing elements obtained.

Taking the influence element of future precipitation as an example, different kinds of statuses can be divided into rainstorm, heavy rainstorm and extra heavy rainstorm, that is, the 24-hour precipitation of 50-99.9 mm is called “rainstorm”, 100-249.9 mm is called “heavy rainstorm”, and more than 250 mm is called “extra heavy rainstorm”.

Step S232.b, analyzing and obtaining similarity of time ratios of occurrence between influencing elements involved in preset different analysis algorithms of geotechnical engineering structure and same one of the influencing elements, according to the time ratios of occurrence of different kinds of statuses of different influencing elements, time ratios of occurrence of corresponding kinds of statuses of the same one influencing element in the status information of influencing elements involved in the preset different analysis algorithms of geotechnical engineering structure.

For example, assuming time of the influencing element A is 1 hour, and time of the influencing element in the first set of analysis algorithm of geotechnical engineering structure being the same as the influencing element A is 30 minutes, then the similarity of time ratio is 50%. If the time of the influencing element in the first set of analysis algorithm of geotechnical engineering structure being the same as the influencing element A is 90 minutes, then the similarity of time ratio is 67%.

Step S232.c, analyzing and determining the similarity between the status information of influencing elements obtained and status information of influencing elements involved in existing analysis algorithm of geotechnical engineering structure, according to the similarity of time ratios of occurrence between influencing elements involved in preset different analysis algorithms of geotechnical engineering structure and the same one of the influencing elements, and the same influencing element, the time ratios of occurrence of different kinds of statuses of the same influencing element.

For example, different kinds of statuses of the same influencing element can be divided into category A and category B. Among them, time ratio of the category A is 30%, time ratio of the category B is 70%. The different kinds of statuses of the same influencing element in the status information of influencing elements involved in the existing analysis algorithm of geotechnical engineering structure can also be divided into category A and category B, where time ratio of the category A is 50% and time ratio of the category B is 50%.

Assuming that the similarity of time ratio of the present influencing element is 50%, the similarity between the present status information of influencing element and the status information of influencing elements involved in existing analysis algorithm of geotechnical engineering structure is calculated as follows: Z=[(30%/70%)/(50%/50%)]*50%=21.4%.

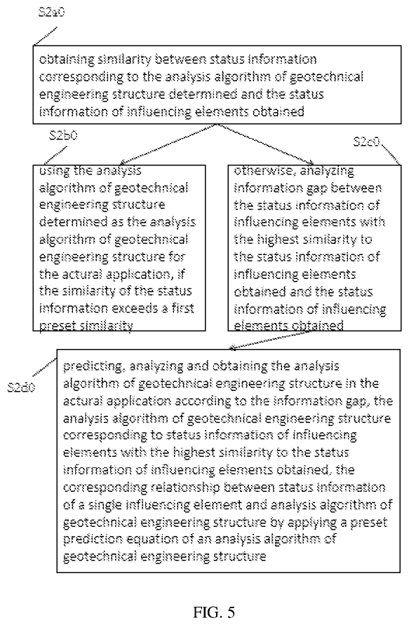

In step S220 of FIG. 2, when further considering the case that the similarity with the analysis algorithm of geotechnical engineering structure corresponding to the status information of influencing element with the highest similarity to the status information of influencing elements obtained cannot meet the requirements, it is also necessary to further analyze the status information of influencing elements with the highest similarity after determining the analysis algorithm of geotechnical engineering structure corresponding to the status information of influencing elements with the highest similarity to the status information of influencing elements obtained. For details refer to the embodiment shown in FIG. 5.

Referring to FIG. 5, a method for modal prediction and analysis of a geotechnical engineering structure further comprises after a step of analyzing and determining an analysis algorithm of geotechnical engineering structure corresponding to status information of influencing elements with the highest similarity to the status information of influencing elements obtained but before a step of using the analysis algorithm of geotechnical engineering structure as an analysis algorithm of geotechnical engineering structure in the actual application:

Step S2a0, obtaining similarity between status information corresponding to the analysis algorithm of geotechnical engineering structure determined and the status information of influencing elements obtained.

Step S2b0, using the analysis algorithm of geotechnical engineering structure determined as the analysis algorithm of geotechnical engineering structure for the actual application, if the similarity of the status information exceeds a first preset similarity.

The first preset similarity can be 70%, but also can be others according to user settings.

Step S2c0, otherwise, analyzing information gap between the status information of influencing elements with the highest similarity to the status information of influencing elements obtained and the status information of influencing elements obtained.

Analyzing information gap between the status information of influencing elements with the highest similarity to the status information of influencing elements obtained and the status information of influencing elements obtained takes the future precipitation as an example, at present, the gap information is difference between the total future precipitation corresponding to the analysis algorithm of geotechnical engineering structure with the highest similarity and the total future precipitation this time. If drainage is taken as an example, the drainage difference is taken as the gap information

Step S2d0, predicting, analyzing and obtaining the analysis algorithm of geotechnical engineering structure in the actual application according to the information gap, the analysis algorithm of geotechnical engineering structure corresponding to status information of influencing elements with the highest similarity to the status information of influencing elements obtained, the corresponding relationship between status information of a single influencing element and analysis algorithm of geotechnical engineering structure by applying a preset prediction equation of an analysis algorithm of geotechnical engineering structure.

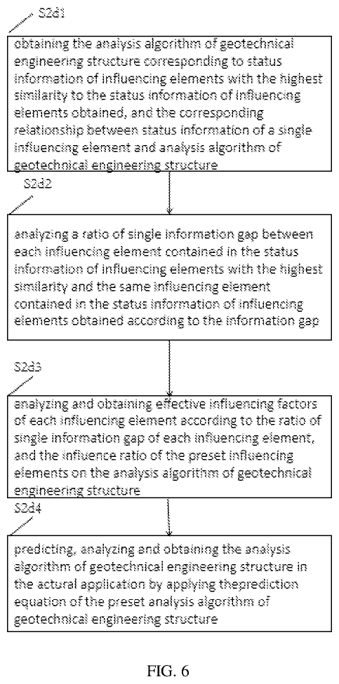

Referring to FIG. 6, a step of predicting and analyzing the analysis algorithm of geotechnical engineering structure in the actual application comprises:

Step S2d1, obtaining the analysis algorithm of geotechnical engineering structure corresponding to status information of influencing elements with the highest similarity to the status information of influencing elements obtained, and the corresponding relationship between status information of a single influencing element and analysis algorithm of geotechnical engineering structure.

The corresponding relationship between status information of a single influencing element and analysis algorithm of geotechnical engineering structure can be queried from a preset database storing the corresponding relationship between status information of a single influencing element and analysis algorithm of geotechnical engineering structure.

Step S2d2, analyzing a ratio of single information gap between each influencing element contained in the status information of influencing elements with the highest similarity and the same influencing element contained in the status information of influencing elements obtained according to the information gap.

Taking influencing element 1 as an example, assuming that the data of the influencing element1 of the analysis algorithm is 10 and the data of the influencing element 1 is 8, the ratio of single information gap is calculated as follows: Z=(10-8)/8=25%.

Step S2d3, analyzing and obtaining effective influencing factors of each influencing element according to the ratio of single information gap of each influencing element, and the influence ratio of the preset influencing elements on the analysis algorithm of geotechnical engineering structure.

The effective influencing factors of each influencing element is the product of the ratio of single information gap of each influencing element and the influence ratio of the preset influencing element on the analysis algorithm of geotechnical engineering structure.

Step S2d4, predicting, analyzing and obtaining the analysis algorithm of geotechnical engineering structure in the actual application by applying the following prediction equation of the preset analysis algorithm of geotechnical engineering structure:

Z=a*q1+q2*[b*(t₁/tₜₒₜₐₗ)+c*(t₂/tₜₒₜₐₗ)+d*(t₃/tₜₒₜₐₗ)+e*(t₄/tₜₒₜₐₗ)]

q1+q2=1, tₜₒₜₐₗ=t₁+t₂+t₃+t₄, where Z is the analysis algorithm of geotechnical engineering structure in the actual application predicted; a is the analysis algorithm of geotechnical engineering structure corresponding to status information of influencing elements with the highest similarity to the status information of influencing elements obtained; q1 is weight coefficient of the analysis algorithm of geotechnical engineering structure corresponding to status information of influencing elements with the highest similarity to the status information of influencing elements obtained; q2 is weight coefficient of the analysis algorithm corresponding to a single influencing element; b is an analysis algorithm of geotechnical engineering structure corresponding to the first single influencing element; t1 is an effective influencing factor of the first single influencing element; c is an analysis algorithm of geotechnical engineering structure corresponding to the second single influencing element; t2 is an effective influencing factor of the second single influencing element; d is an analysis algorithm of geotechnical engineering structure corresponding to the third single influencing element; t3 is an effective influencing factor of the third single influencing element; e is an analysis algorithm of geotechnical engineering structure corresponding to the fourth single influencing element; t4 is an effective influencing factor of the fourth single influencing element.

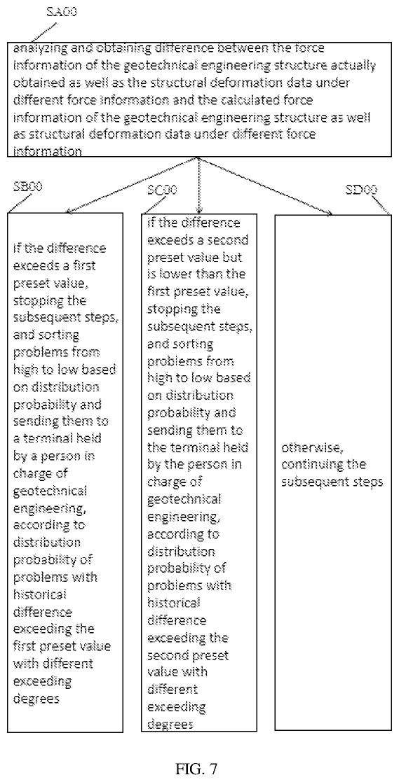

Between step S300 and step S400 in FIG. 1, there is a large gap between the actual data and the training data before revising the analysis algorithm of geotechnical engineering structure, which is unfavorable to the revision through the neural network algorithm at this time. So, it is necessary to make further analysis and the cause should be notified to the person in charge. For details refer to the embodiment shown in FIG. 7.

Referring to FIG. 7, a method for modal prediction and analysis of a geotechnical engineering structure further includes after a step of o obtaining force information of the geotechnical engineering structure actually obtained and structural deformation data under different force information as actual data but before a step of revising the analysis algorithm of geotechnical engineering structure:

Step SA00, analyzing and obtaining difference between the force information of the geotechnical engineering structure actually obtained as well as the structural deformation data under different force information and the calculated force information of the geotechnical engineering structure as well as structural deformation data under different force information;

Step SB00, if the difference exceeds a first preset value, stopping the subsequent steps, and sorting problems from high to low based on distribution probability and sending them to a terminal held by a person in charge of geotechnical engineering, according to distribution probability of problems with historical difference exceeding the first preset value with different exceeding degrees.

The first preset value can be 10000N or other preset force values. The distribution probability of problems exceeding the first preset value with different exceeding degrees can be obtained by querying from a preset database storing the distribution probability of problems exceeding the first preset value with different exceeding degrees. The terminal held by the person in charge of geotechnical engineering can be mobile phones, computers or other communication terminals.

The problems may be problems of the detection device adaptive for actual detection, or problems of the applied algorithm.

Step SC00, if the difference exceeds a second preset value but is lower than the first preset value, stopping the subsequent steps, and sorting problems from high to low based on distribution probability and sending them to the terminal held by the person in charge of geotechnical engineering, according to distribution probability of problems with historical difference exceeding the second preset value with different exceeding degrees.

The distribution probability of problems with historical difference exceeding the second preset value with different exceeding degrees can be queried from a preset database storing the distribution probability of problems with historical difference exceeding the second preset value with different exceeding degrees.

Step SD00, otherwise, continuing the subsequent steps.

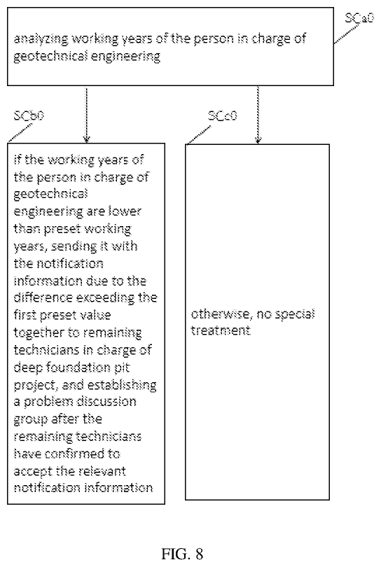

The person in charge of geotechnical engineering mentioned in the terminal held by the person in charge of geotechnical engineering in step SB00 must make selection, so that the person in charge of geotechnical engineering notified can effectively handle corresponding problems. For details refer to the embodiment in FIG. 8.

Referring to FIG. 8, the person in charge of geotechnical engineering is selected as follows:

Step SCa0, analyzing working years of the person in charge of geotechnical engineering.

The working years of the person in charge of geotechnical engineering can be queried from a preset database storing the working years of the person in charge of geotechnical engineering.

Step SCb0, if the working years of the person in charge of geotechnical engineering are lower than preset working years, sending it with the notification information due to the difference exceeding the first preset value together to remaining technicians in charge of deep foundation pit project, and establishing a problem discussion group after the remaining technicians have confirmed to accept the relevant notification information.

The preset working years can be one year or others.

Step SCc0, otherwise, no special treatment.

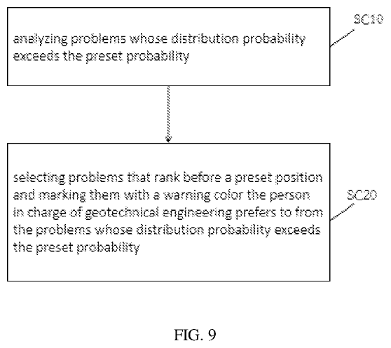

When notifying the person in charge of geotechnical engineering, in order to attract attention of the person in charge to the problems with higher probability, it is necessary to make further analysis between sorting the problems from high to low according to the distribution probability and sending them to the terminal held by the person in charge of geotechnical engineering. For details, refer to the embodiment shown in FIG. 9.

Referring to FIG. 9, a method for modal prediction and analysis of a geotechnical engineering structure further comprises between a step of sorting problems from high to low based on distribution probability and a step of sending to the terminal held by the person in charge of geotechnical engineering:

Step SC10, analyzing problems whose distribution probability exceeds the preset probability.

Step SC20, selecting problems that rank before a preset position and marking them with a warning color the person in charge of geotechnical engineering prefers to from the problems whose distribution probability exceeds the preset probability.

The preset probability can be 30% or other probability set by user. The warning color the person in charge prefers to can be red or blue or other colors which are selected by user based on actual requirements.

Based on the same conception, a system for modal prediction and analysis of a geotechnical engineering structure is disclosed, including:
a memory;
a processor; and
a program, which is stored on the memory and can run on the processor, to realize the method according to FIG. 1 to FIG. 9.

The embodiments of the present disclosure are preferred embodiments of the application, which do not limit the protection scope of the present application. Therefore, any equivalent changes made according to the structure, shape and principle of the application should be covered in the protection scope of the application.

What is claimed is:

1. A method for modal prediction and analysis of a geotechnical engineering structure, comprising:
obtaining a design model of the geotechnical engineering structure and status information of influencing elements during a planned geotechnical engineering, wherein the influencing elements includes construction environment, load conditions, drainage and future precipitation;
analyzing and determining an analysis algorithm of geotechnical engineering structure corresponding to the status information of influencing elements obtained according to a corresponding relationship between the status information of influencing elements and analysis algorithm of geotechnical engineering structure, and modal predicting the design model of the geotechnical engineering structure by using a corresponding analysis algorithm of geotechnical engineering structure, so as to calculate force information of the geotechnical engineering structure and modal deformation data of soil-structure under different force information as training data;
obtaining force information of the geotechnical engineering structure actually obtained and structural deformation data under different force information as actual data;
revising the analysis algorithm of geotechnical engineering structure based on the training data and actual data by applying a pre-built neural network algorithm;
wherein a step of analyzing and determining an analysis algorithm of geotechnical engineering structure corresponding to the status information of influencing elements obtained includes:
querying, whether there is an analysis algorithm of geotechnical engineering structure corresponding to the status information of influencing elements obtained, according to the corresponding relationship between the status information of influencing elements and analysis algorithm of geotechnical engineering structure;
if yes, using the analysis algorithm of geotechnical engineering structure corresponding to the status information of influencing elements obtained as the analysis algorithm of geotechnical engineering structure determined; and
if not, querying an analysis algorithm of geotechnical engineering structure corresponding to status information of other influencing elements, and analyzing and determining an analysis algorithm of geotechnical engineering structure corresponding to status information of influencing elements with the highest similarity to the status information of influencing elements obtained, as an analysis algorithm of geotechnical engineering structure for an actual application.

2. The method for modal prediction and analysis of a geotechnical engineering structure according to claim 1, wherein a step of analyzing and determining an analysis algorithm of geotechnical engineering structure corresponding to status information of influencing elements with the highest similarity to the status information of influencing elements obtained comprises:
analyzing similarity between the status information of influencing elements obtained and status information of influencing elements involved in existing analysis algorithm of geotechnical engineering structure;
analyzing and determining the analysis algorithm of geotechnical engineering structure corresponding to status information of influencing elements with the highest similarity to the status information of influencing elements obtained based on the similarity between the status information of influencing elements obtained and status information of influencing elements involved in existing analysis algorithm of geotechnical engineering structure and influence ratio of preset influencing elements on the analysis algorithm of geotechnical engineering structure; and
using the analysis algorithm of geotechnical engineering structure determined as the analysis algorithm of geotechnical engineering structure in the actual application.

3. The method for modal prediction and analysis of a geotechnical engineering structure according to claim 2, wherein a step of analyzing similarity between the status information of influencing elements obtained and status information of influencing elements involved in existing analysis algorithm of geotechnical engineering structure comprises:
analyzing time ratios of occurrence of different kinds of statuses of different influencing elements in the status information of influencing elements obtained;
analyzing and obtaining similarity of time ratios of occurrence between influencing elements involved in preset different analysis algorithms of geotechnical engineering structure and same one of the influencing elements, according to the time ratios of occurrence of different kinds of statuses of different influencing elements, time ratios of occurrence of corresponding kinds of statuses of the same one influencing element in the status information of influencing elements involved in the preset different analysis algorithms of geotechnical engineering structure; and
analyzing and determining the similarity between the status information of influencing elements obtained and status information of influencing elements involved in existing analysis algorithm of geotechnical engineering structure, according to the similarity of time ratios of occurrence between influencing elements involved in preset different analysis algorithms of geotechnical engineering structure and the same one of the influencing elements, and the same influencing element, the time ratios of occurrence of different kinds of statuses of the same influencing element.

4. The method for modal prediction and analysis of a geotechnical engineering structure according to claim 1, further comprising after a step of analyzing and determining an analysis algorithm of geotechnical engineering structure corresponding to status information of influencing elements with the highest similarity to the status information of influencing elements obtained but before a step of using the analysis algorithm of geotechnical engineering structure as an analysis algorithm of geotechnical engineering structure in the actual application:
obtaining similarity between status information corresponding to the analysis algorithm of geotechnical engineering structure determined and the status information of influencing elements obtained;
using the analysis algorithm of geotechnical engineering structure determined as the analysis algorithm of geotechnical engineering structure for the actual application, if the similarity of the status information exceeds a first preset similarity;
if not, analyzing information gap between the status information of influencing elements with the highest similarity to the status information of influencing elements obtained and the status information of influencing elements obtained; and
predicting, analyzing and obtaining the analysis algorithm of geotechnical engineering structure in the actual application according to the information gap, the analysis algorithm of geotechnical engineering structure corresponding to status information of influencing elements with the highest similarity to the status information of influencing elements obtained, the corresponding relationship between status information of a single influencing element and analysis algorithm of geotechnical engineering structure by applying a preset prediction equation of an analysis algorithm of geotechnical engineering structure.

5. The method for modal prediction and analysis of a geotechnical engineering structure according to claim 4, wherein a step of predicting and analyzing the analysis algorithm of geotechnical engineering structure in the actual application comprises:
obtaining the analysis algorithm of geotechnical engineering structure corresponding to status information of influencing elements with the highest similarity to the status information of influencing elements obtained, and the corresponding relationship between status information of a single influencing element and analysis algorithm of geotechnical engineering structure;
analyzing a ratio of single information gap between each influencing element contained in the status information of influencing elements with the highest similarity and the same influencing element contained in the status information of influencing elements obtained according to the information gap;
analyzing and obtaining effective influencing factors of each influencing element according to the ratio of single information gap of each influencing element, and the influence ratio of the preset influencing elements on the analysis algorithm of geotechnical engineering structure; and
predicting, analyzing and obtaining the analysis algorithm of geotechnical engineering structure in the actual application by applying the following prediction equation of the preset analysis algorithm of geotechnical engineering structure:
Z=a*q1+q2*[b*(t₁/tₜₒₜₐₗ)+c*(t₂/tₜₒₜₐₗ)+d*(t₃/tₜₒₜₐₗ)+e*(t₄/tₜₒₜₐₗ)]
q1+q2=1, tₜₒₜₐₗ=t₁+t₂+t₃+t₄, where
Z is the analysis algorithm of geotechnical engineering structure in the actual application predicted,
a is the analysis algorithm of geotechnical engineering structure corresponding to status information of influencing elements with the highest similarity to the status information of influencing elements obtained,
q1 is weight coefficient of the analysis algorithm of geotechnical engineering structure corresponding to status information of influencing elements with the highest similarity to the status information of influencing elements obtained,
q2 is weight coefficient of the analysis algorithm corresponding to a single influencing element,
b is an analysis algorithm of geotechnical engineering structure corresponding to the first single influencing element,
t₁ is an effective influencing factor of the first single influencing element,
c is an analysis algorithm of geotechnical engineering structure corresponding to the second single influencing element,
t₂ is an effective influencing factor of the second single influencing element,
d is an analysis algorithm of geotechnical engineering structure corresponding to the third single influencing element,
t₃ is an effective influencing factor of the third single influencing element,
e is an analysis algorithm of geotechnical engineering structure corresponding to the fourth single influencing element, and
t₄ is an effective influencing factor of the fourth single influencing element.

6. The method for modal prediction and analysis of a geotechnical engineering structure according to claim 1, further comprising after a step of obtaining force information of the geotechnical engineering structure actually obtained and structural deformation data under different force information as actual data but before a step of revising the analysis algorithm of geotechnical engineering structure:
analyzing and obtaining difference between the force information of the geotechnical engineering structure actually obtained as well as the structural deformation data under different force information and the calculated force information of the geotechnical engineering structure as well as structural deformation data under different force information;
if the difference exceeds a first preset value, stopping the subsequent steps, and sorting problems from high to low based on distribution probability and sending them to a terminal held by a person in charge of geotechnical engineering, according to distribution probability of problems with historical difference exceeding the first preset value with different exceeding degrees,
if the difference exceeds a second preset value but is lower than the first preset value, stopping the subsequent steps, and sorting problems from high to low based on distribution probability and sending them to the terminal held by the person in charge of geotechnical engineering, according to distribution probability of problems with historical difference exceeding the second preset value with different exceeding degrees; and
if not, proceeding to subsequent steps.

7. The method for modal prediction and analysis of a geotechnical engineering structure according to claim 6, wherein the person in charge of geotechnical engineering is selected as follows:
analyzing working years of the person in charge of geotechnical engineering;
if the working years of the person in charge of geotechnical engineering are lower than preset working years, sending it with the notification information due to the difference exceeding the first preset value together to remaining technicians in charge of deep foundation pit project, and establishing a problem discussion group after the remaining technicians have confirmed to accept the relevant notification information;
if not, taking no action.

8. The method for modal prediction and analysis of a geotechnical engineering structure according to claim 6, further comprising between a step of sorting problems from high to low based on distribution probability and a step of sending to the terminal held by the person in charge of geotechnical engineering:
analyzing problems in which distribution probability exceeds the preset probability;
selecting problems that rank before a preset position and marking them with a warning color preferred by the person in charge of geotechnical engineering from the problems in which distribution probability exceeds the preset probability.

9. A system for modal prediction and analysis of a geotechnical engineering structure, comprising:
a memory;
a processor; and
a program, which is stored on the memory and can run on the processor,
wherein the program can be loaded and executed on the processor, to realize the method for modal prediction and analysis of a geotechnical engineering structure according to claim 1.
